(19) United States
(12) Patent Application Publication
(10) Pub. No.: US 2026/0352252 A1
(43) Pub. Date: Nov. 5, 2026

(54) ON-CHIP NOISE SOURCE

(71) Applicant: QUALCOMM Incorporated, San Diego, CA (US)

(72) Inventors: Mohammad OVEISI, Irvine, CA (US); Rabih MAKAREM, Irvine, CA (US); Shervin MOLOUDI, Los Angeles, CA (US)

(21) Appl. No.: 19/199,066

(22) Filed: May 5, 2025

(51) Int. Cl. H04B 1/405; H04B 1/04

(52) U.S. Cl. CPC H04B 1/405; H04B 1/04; H04B 2001/0416

(57) ABSTRACT

Certain aspects of the present disclosure provide techniques for an on-chip noise source. An example radio frequency circuit includes a transceiver package comprising a signal chain comprising one or more mixers coupled to one or more amplifiers. The transceiver package further includes a noise source circuit coupled to the signal chain. The noise source circuit comprises a noise generator circuit comprising a first inverter topology, wherein the noise generator circuit is configured to output noise within a range of frequencies; and an amplifier circuit comprising a second inverter topology, wherein the amplifier circuit is coupled to the noise generator circuit, wherein the amplifier circuit is configured to amplify the noise and feed the amplified noise to the signal chain.

### INTRODUCTION

### Field of the Disclosure

Aspects of the present disclosure relate to radio frequency circuitry, and more particularly, to an on-chip noise source for radio frequency circuitry.

### Description of Related Art

Wireless communications systems are widely deployed to provide various telecommunication services such as telephony, video, data, messaging, broadcasts, etc. These wireless communications systems may employ multiple-access technologies capable of supporting communications with multiple users by sharing available wireless communications system resources with those users. Wireless communication devices may communicate radio frequency (RF) signals via any of various suitable radio access technologies (RATs) including, but not limited to, 5G New Radio (NR), Evolved Universal Terrestrial Radio Access (E-UTRA), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., Institute of Electrical and Electronics Engineers (IEEE) 802.11 specifications), any future RAT, and/or the like.

In certain cases, a wireless communications device is equipped with a RF transceiver (also referred to as an RF front-end) for communicating RF signals. In general, a baseband signal is modulated to convey information using a modulation technique, such as phase-shift keying (PSK) or any other suitable modulation technique. In a transmit mode, the RF transceiver is responsible for multiplexing the baseband signal with an RF carrier signal that is transmitted over the air (e.g., a wireless communication channel). Such an operation is called upconversion. In a receive mode, the RF transceiver converts a received RF signal to the baseband signal. Such an operation is called downconversion. The received baseband signal then can be demodulated into the information encoded at a transmitter. The RF transceiver may include a cascade of components in a transmit chain and a receive chain, respectively. The cascade of components may include, for example, one or more of attenuators, switches, couplers, filters, mixers, amplifiers, frequency synthesizers, oscillators, antenna tuners, duplexers, diplexers, detectors, etc.

Although there have been great technological advancements in RF circuitry over many years, challenges still exist. For example, RF circuitry can still encounter various sources of noise. Accordingly, there is a continuous desire to improve the technical performance of RF circuitry, such as characterization of a noise figure associated with RF circuitry.

### SUMMARY

Certain aspects provide a radio frequency (RF) circuit. The RF circuit includes a transceiver package comprising a signal chain comprising one or more mixers coupled to one or more amplifiers. The transceiver package further includes a noise source circuit coupled to the signal chain. The noise source circuit comprises a noise generator circuit comprising a first inverter topology, wherein the noise generator circuit is configured to output noise within a range of frequencies; and an amplifier circuit comprising a second inverter topology, wherein the amplifier circuit is coupled to the noise generator circuit, wherein the amplifier circuit is configured to amplify the noise and feed the amplified noise to the signal chain.

Certain aspects provide a radio frequency (RF) circuit. The RF circuit includes a transceiver package comprising a signal chain comprising one or more mixers coupled to one or more amplifiers. The transceiver package further includes a current-mode noise source circuit coupled to the signal chain, wherein the current-mode noise source circuit is configured to feed noise to the signal chain. The current-mode noise source circuit comprises an output node; a current-mirror circuit; an amplifier circuit coupled to the output node and the current-mirror circuit; a current-sink circuit coupled to the output node and the current-mirror circuit; and a variable resistive element coupled to the output node.

Certain aspects provide a method for noise figure characterization of a signal chain. The method includes feeding, via a noise source circuit to a signal chain at a first time occasion, first noise at a first power level associated with a first state, wherein a transceiver package comprises the signal chain and the noise source circuit, wherein the signal chain comprises one or more mixers coupled to one or more amplifiers, wherein the noise source circuit comprises a noise generator circuit and an amplifier circuit. The method further includes feeding, via the noise source circuit to the signal chain at a second time occasion, second noise at a second power level associated with a second state. The method further includes obtaining a first characteristic associated with the signal chain based on the first noise fed at the first power level. The method further includes obtaining a second characteristic associated with the signal chain based on the second noise fed at the second power level. The method further includes determining a noise figure associated with the signal chain based at least in part on a comparison of the first characteristic and the second characteristic.

Certain aspects provide a method for noise figure characterization of a signal chain. The method includes feeding, via a noise source circuit to a signal chain at a first time occasion, first noise at a first power level associated with a first state, wherein a transceiver package comprises the signal chain and the noise source circuit, wherein the signal chain comprises one or more mixers coupled to one or more amplifiers, wherein the noise source circuit comprises an output node, a noise generator circuit, a current-mirror circuit, an amplifier circuit, a current-sink circuit, a variable resistive element. The method further includes feeding, via the noise source circuit to the signal chain at a second time occasion, second noise at a second power level associated with a second state. The method further includes obtaining a first characteristic associated with the signal chain based on the first noise fed at the first power level. The method further includes obtaining a second characteristic associated with the signal chain based on the second noise fed at the second power level. The method further includes determining a noise figure associated with the signal chain based at least in part on a comparison of the first characteristic and the second characteristic.

Other aspects provide: an apparatus operable, configured, or otherwise adapted to perform any one or more of the aforementioned methods and/or those described elsewhere herein; a non-transitory, computer-readable medium comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 depicts an example wireless communications system.

FIG. 2 depicts an example wireless communications device communicating with another device.

FIG. 3 depicts an example architecture for in situ noise figure characterization of a signal chain.

FIG. 4 depicts an example architecture of an amplifier-based noise source circuit.

FIG. 5 depicts an example architecture of a current-mode noise source circuit.

FIG. 6 depicts an example method for in situ noise figure characterization of a signal chain.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Aspects of the present disclosure provide apparatuses, methods, processing systems, and computer-readable mediums for an on-chip noise source. As used herein, an on-chip noise source refers to a noise source included in or integrated with a device (such as a radio frequency transceiver). A device including an electronic assembly (such as a chip, package, portable electronic device, cell phone, laptop, or the like) may undergoing testing, such as calibration testing, noise figure characterization, or the like. As an example, the on-chip noise source may be included in or integrated with a circuit package (e.g., a transceiver package) that includes the device. The circuit package may be or include a chip, system on chip (SoC), system in package (SiP), chipset, package, circuit board (e.g., printed circuit board), motherboard, and/or mainboard that includes the device.

Radio frequency (RF) circuitry (such as an RF transceiver) encounter various sources of noise, which can impact the signal quality of signals that pass through the RF circuitry, such as received signals. As an example, thermal noise is the electrical noise generated by the thermal agitation of electrons in an electrical conductor; and thermal noise is generally present in all electrical circuits (such as an RF transceiver). In certain cases, thermal noise can even drown out weak signals, such as low power received signals that are processed through an RF receiver. A noise figure can be used to characterize the noise added or generated by an electrical system, such as an RF receiver. The noise figure of an electrical system characterizes the decrease or degradation in the signal-to-noise ratio (SNR) as a signal passes through the electrical system. In general, the noise figure characterizes the ability of an electrical system to process low-power or weak signals. Thus, the noise figure can be used to determine mechanisms to compensate for or adjust the noise added or generated by the electrical system, such as adjusting an antenna gain or minimizing the noise generated within receiver components.

Technical problems for noise figure characterization include, for example, effective characterization of the noise figure using an on-chip noise source. In certain cases, the noise figure of a device, such as an RF receiver, is measured using automated test equipment (ATE), such as a noise figure analyzer, in a controlled testing environment, such as a Faraday cage, to minimize outside noise. Due to the noise figure analyzer being arranged external to the device, the noise figure of the device is effectively only measured once under a fixed set of operating conditions (e.g., power, voltage, temperature, etc.) of the device. However, the noise figure of the device is expected to vary over various operating conditions, and in some cases, the noise figure may change over the operating life of the device. Thus, the noise figure measurements using an ATE may effectively provide one-time characterization of the noise figure for a device.

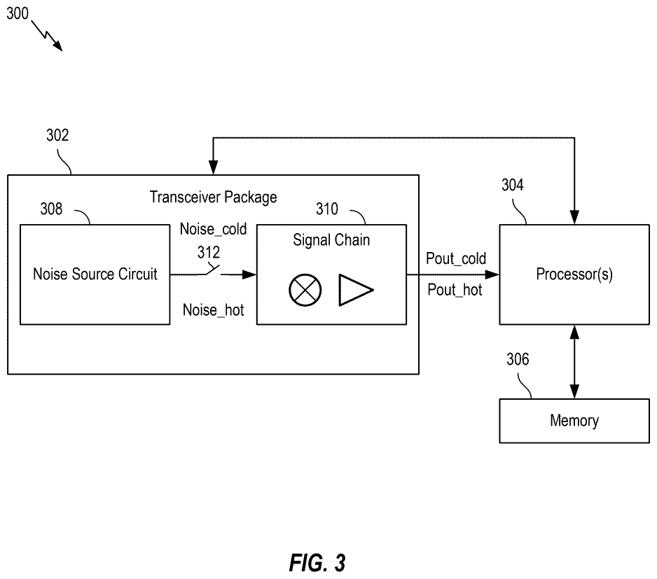

One example of an on-chip noise source includes a current-mirror-based noise source. The on-chip noise source uses a resistor for a cold state noise figure measurement and the current-mirror-based noise source for a hot state noise figure measurement, for example, as part of a Y-factor method of characterizing the noise figure (as further described herein with respect to FIG. 3). However, the noise power in the cold state may be too weak to reliably measure the output power of the device. In certain cases, scaling the circuit architecture of the current-mirror-based noise source to have a higher excess noise ratio (which is preferable for the hot state of the noise source) may result in the current-mirror path using a relatively large mirror transistor, which would occupy a non-trivial amount of chip space or area and consume a non-trivial amount of power. In certain cases, increasing the output current for the larger transistors may cause the current-mirror path to operate in the triode region, which may reduce the output resistance in the hot state, cause a larger variation in the output impedance of the noise source (which affects the accuracy of the noise figure measurement), and affect the operating bandwidth of the noise source. In certain cases, the output impedance of the on-chip noise source can change significantly with various process-voltage-temperature corners. Thus, the output impedance may vary between the hot and cold states, which may impact the accuracy of the noise figure measurements.

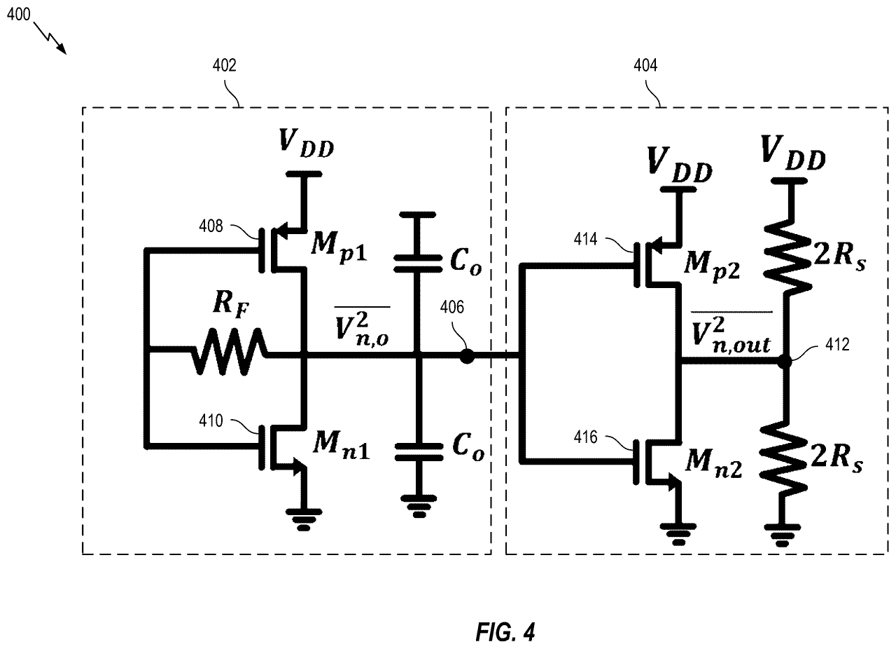

Certain aspects described herein may overcome the aforementioned technical problem(s), for example, by providing circuit architectures for an on-chip noise source that may enable dynamic, accurate, and/or reliable noise figure measurements while maintaining a high ENR for the cold and hot state measurements. In certain aspects, an example noise source may include an amplifier-based noise source, for example, as further described herein with respect to FIG. 4. The amplifier-based noise source may include a noise generator circuit (such as an inverter-based circuit) and an amplifier circuit (such as an inverter-based amplifier). The amplifier-based noise source may enable noise figure measurements across a wide frequency bandwidth.

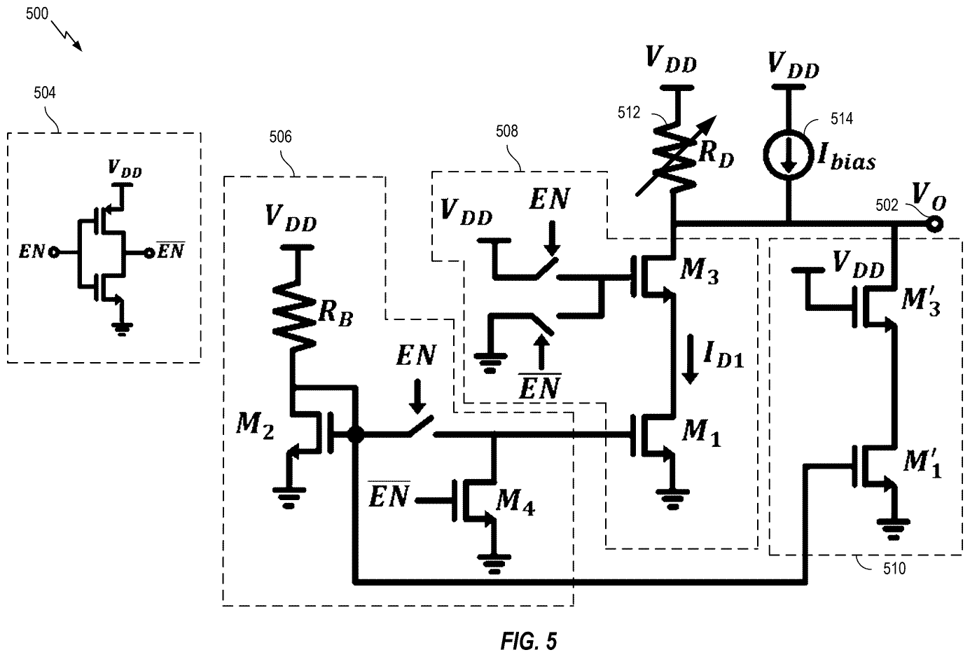

In certain aspects, another example noise source may include a current-mode noise source. The current-mode noise source may include a current-sink circuit to increase the output power of the noise source without driving certain transistors of the noise source into the triode region, for example, as further described herein with respect to FIG. 5. The current-mode noise source may include a variable resistive element (such as a digital potentiometer) to adjust the output impedance of the noise source for the cold state and hot state measurements.

Certain architectures of an on-chip noise source described herein may provide various beneficial technical effects and/or advantages. The architectures of an on-chip noise source may enable dynamic, accurate, and/or reliable noise figure measurements. In certain cases, the on-chip noise source circuit architectures may enable noise figure measurements to be obtained throughout the operational life of a device, for example, an RF transceiver. Such noise figure measurements may enable the RF transceiver to dynamically compensate for changes in the noise figure, for example, by adjusting certain gain states applied to signal chains (e.g., a transmit chain and/or receive chain) of the RF transceiver.

In certain cases, the on-chip noise source circuit architectures may enable noise figure characterizations to adapt to changes or variations in the fabrication processes used to fabricate an integrated circuit. As an example, an integrated circuit may be designed by fabricating multiple chips with different combinations of fabrication parameters referred to as process corners. The on-chip noise circuit may enable reduced processing time in developing a noise figure characterization per process corner among the variations of the integrated circuit design.

In certain cases, the improved accuracy and/or reliability of the noise figure measurements may be attributable to the amplifier-based architecture and/or the current-sink circuit and/or the variable resistive element used in the current-mode noise source. For example, the current-sink circuit and/or the variable resistive element may ensure the noise source has a stable output impedance for the cold state and hot state measurements. Thus, the current-sink circuit and/or the variable resistive element may ensure that the only difference between the cold state and hot state measurements is the power of the noise fed to the device, which in turn enables accurate and/or reliable noise figure measurements.

### Example Wireless Communications System

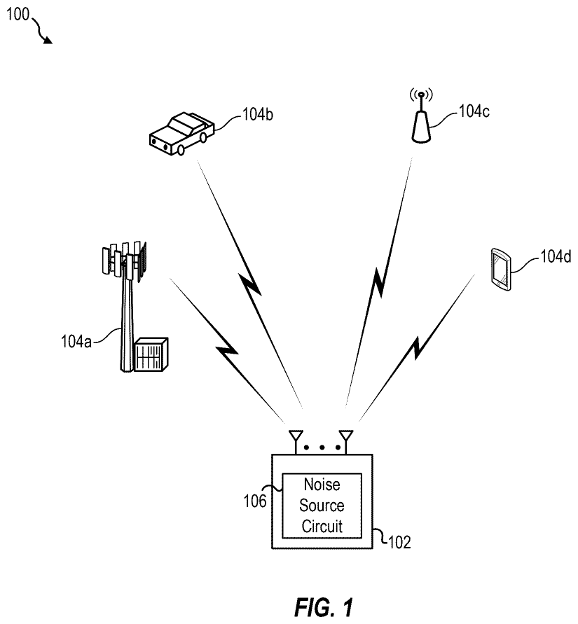

FIG. 1 illustrates an example wireless communications system 100 in which aspects of the present disclosure may be performed. For example, the wireless communications system 100 may include a wireless wide area network (WWAN) and/or a wireless local area network (WLAN). A WWAN may include a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation (2G) or Third Generation (3G) network), a code division multiple access (CDMA) system (e.g., a 2G/3G network), any future WWAN system, or any combination thereof. A WLAN may include a wireless network configured for communications according to an Institute of Electrical and Electronics Engineers (IEEE) standard such as one or more of the 802.11 standards, etc. In some cases, the wireless communications system 100 may include a device-to-device (D2D) communications network or a short-range communications system, such as Bluetooth communications or near field communications (NFC).

As illustrated in FIG. 1, the wireless communications system 100 may include a first wireless device 102 communicating with any of various second wireless devices 104a-d (hereinafter “the second wireless device 104”) via any of various radio access technologies (RATs), where a wireless device may refer to a wireless communications device. The RATs may include, for example, WWAN communications (e.g., E-UTRA and/or 5G NR), WLAN communications (e.g., IEEE 802.11), vehicle-to-everything (V2X) communications, non-terrestrial network (NTN) communications, short-range communications (e.g., Bluetooth), D2D communications, etc.

The first wireless device 102 may include any of various wireless communications devices including a user equipment (UE), a base station, a wireless station, an access point, customer-premises equipment (CPE), etc. In certain aspects, the first wireless device 102 includes a noise source circuit 106 that enables on-chip noise figure characterization of a signal chain, in accordance with aspects of the present disclosure.

The second wireless device 104 may include, for example, a base station 104a, a vehicle 104b, an access point (AP) 104c, and/or a UE 104d. Further, the wireless communications systems 100 may include terrestrial aspects, such as ground-based network entities (e.g., the base station 104a and/or access point 104c), and/or non-terrestrial aspects, such as a spaceborne platform and/or an aerial platform, which may include network entities on-board (e.g., one or more base stations) capable of communicating with other network elements (e.g., terrestrial base stations) and/or user equipment.

The base station 104a may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and/or others. The base station 104a may provide communications coverage for a respective geographic coverage area, which may sometimes be referred to as a cell, and which may overlap in some cases (e.g., a small cell may have a coverage area that overlaps the coverage area of a macro cell). A base station may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

The first wireless device 102 and/or the UE 104d may generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. A UE may also be referred to more generally as a mobile device, a wireless device, a wireless communications device, a wireless station (STA), a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and other terms.

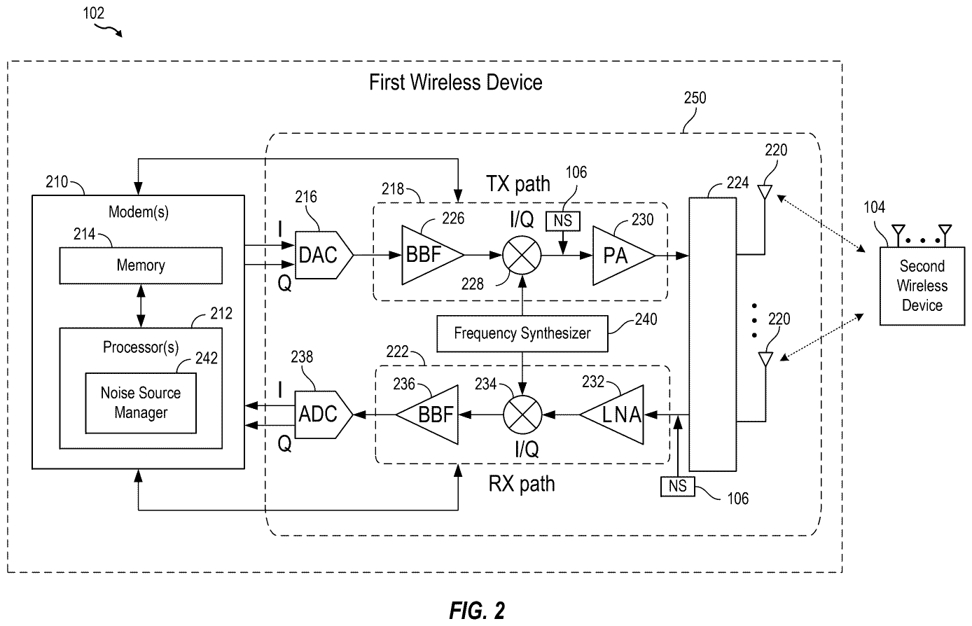

FIG. 2 illustrates example components of the first wireless device 102, which may be used to communicate with any of the second wireless devices 104.

The first wireless device 102 may be, or may include, a chip, system on chip (SoC), system in package (SiP), chipset, package, device that includes one or more modems 210 (hereinafter “the modem 210”). In some cases, the modem 210 may include, for example, any of a WWAN modem (e.g., a modem configured to communicate via E-UTRA, 5G NR, and/or any future WWAN communications standards), a WLAN modem (e.g., a modem configured to communicate via IEEE 802.11 standards), a Bluetooth modem, a NTN modem, etc. In certain aspects, the first wireless device 102 also includes one or more RF transceivers (hereinafter “the RF transceiver 250”). In some cases, the RF transceiver 250 or a portion thereof may be referred to as an RF front end (RFFE). In certain cases, the RF transceiver 250 may be or include a software-defined radio, for example, a programmable transceiver. In some aspects, the modem 210 further includes one or more processors, processing blocks or processing elements (hereinafter “the processor 212”) and one or more memory blocks or elements (hereinafter “the memory 214”). In some cases, the processor 212 may implement and/or include a noise source manager 242 that controls the noise figure characterization of a signal chain as further described herein with respect to FIG. 3. In certain aspects, the processor 212 and/or the memory 214 are implemented external or otherwise separate from the modem 210.

In certain aspects, the processor 212 may process any of certain protocol stack layers associated with a radio access technology (RAT). For example, the processor 212 may process any of an application layer, packet layer, WLAN protocol stack layers (e.g., a link or a medium access control (MAC) layer), and/or WWAN protocol stack layers (e.g., a radio resource control (RRC) layer, a packet data convergence protocol (PDCP) layer, a radio link control (RLC) layer, and a MAC layer).

The modem 210 may generally be configured to implement a physical (PHY) layer. For example, the modem 210 may be configured to modulate packets and to output the modulated packets to the RF transceiver 250 for transmission over a wireless medium. The modem 210 is similarly configured to obtain modulated packets received by the RF transceiver 250 and to demodulate the packets to provide demodulated packets. In addition to a modulator and a demodulator, the modem 210 may further include digital signal processing (DSP) circuitry, automatic gain control (AGC), a coder, a decoder, a multiplexer, and/or a demultiplexer (not shown).

As an example, while in a transmission mode, the modem 210 may obtain data from a data source, such as an application processor. The data may be provided to a coder, which encodes the data to provide encoded bits. The encoded bits may be mapped to points in a modulation constellation (e.g., using a selected modulation and coding scheme) to provide modulated symbols. The modulated symbols may be mapped, for example, to spatial stream(s) or space-time streams. The modulated symbols may be multiplexed, transformed via an inverse fast Fourier transform (IFFT) block, and subsequently provided to DSP circuitry for transmit windowing and filtering. The digital signals may be provided to a digital-to-analog converter (DAC) 216. In certain aspects involving beamforming, the modulated symbols in the respective spatial streams may be precoded via a steering matrix prior to provision to the IFFT block.

The modem 210 may be coupled to the RF transceiver 250 by a transmit (TX) path 218 (also known as a transmit chain) for transmitting signals via one or more antennas 220 (hereinafter “the antennas 220”) and a receive (RX) path 222 (also known as a receive chain) for receiving signals via the antennas 220. When the TX path 218 and the RX path 222 share the antennas 220, the paths may be coupled to the antennas 220 via an interface 224, which may include any of various suitable RF devices, such as a balun, a transformer, an antenna tuner, a switch (e.g., an antenna switch module), a duplexer, a diplexer, a multiplexer, and or like. As an example, the modem 210 may output digital in-phase (I) and/or quadrature (Q) baseband signals representative of the respective symbols to the DAC 216. In some examples, all or most of the elements illustrated as being included in the RF transceiver 250 are implemented in a single chip or die. For example, in some configurations, all of the elements of the RF transceiver except the antennas 220 are implemented on a single chip. In some other configurations, the interface 224 or a portion thereof is also omitted from the single chip.

Receiving I or Q baseband analog signals from the DAC 216, the TX path 218 may include a baseband filter (BBF) 226, a mixer 228 (which may include one or several mixers), and a power amplifier (PA) 230. The BBF 226 filters the baseband signals received from the DAC 216, and the mixer 228 mixes the filtered baseband signals with a transmit local oscillator (LO) signal to convert the baseband signal to a different frequency (e.g., upconvert from a baseband frequency to a radio frequency). In some aspects, the frequency conversion process produces the sum and difference frequencies between the LO frequency and the frequencies of the baseband signal. The sum and difference frequencies are referred to as the beat frequencies. Some beat frequencies are in the RF range, such that the signals output by the mixer 228 are typically RF signals, which may be amplified by the PA 230 before transmission by the antennas 220. The antennas 220 may emit RF signals, which may be received at the second wireless device 104. While one mixer 228 is illustrated, several mixers may be used to upconvert the filtered baseband signals to one or more intermediate frequencies and to thereafter upconvert the intermediate frequency signals to a frequency for transmission.

The RX path 222 may include a low noise amplifier (LNA) 232, a mixer 234 (which may include one or several mixers), and a baseband filter (BBF) 236. RF signals received via the antennas 220 (e.g., from the second wireless device 104) may be amplified by the LNA 232, and the mixer 234 mixes the amplified RF signals with a receive local oscillator (LO) signal to convert the RF signal to a baseband frequency (e.g., downconvert the RF signal to the baseband frequency). The baseband signals output by the mixer 234 may be filtered by the BBF 236 before being converted by an analog-to-digital converter (ADC) 238 to digital I or Q signals for digital signal processing. The modem 210 may receive the digital I or Q signals and further process the digital signals, for example, demodulating the digital signals into information.

Certain transceivers may employ frequency synthesizers with a voltage-controlled oscillator (VCO) to generate a stable, tunable LO frequency with a particular tuning range. Thus, the transmit LO frequency may be produced by a frequency synthesizer 240, which may be buffered or amplified by an amplifier (not shown) before being mixed with the baseband signals in the mixer 228. Similarly, the receive LO frequency may be produced by the frequency synthesizer 240, which may be buffered or amplified by an amplifier (not shown) before being mixed with the RF signals in the mixer 234. Separate frequency synthesizers may be used for the TX path 218 and the RX path 222.

While in a reception mode, the modem 210 may obtain digitally converted signals via the ADC 238 and RX path 222. As an example, in the modem 210, digital signals may be provided to the DSP circuitry, which is configured to acquire a received signal, for example, by detecting the presence of the signal and estimating the initial timing and frequency offsets. The DSP circuitry is further configured to digitally condition the digital signals, for example, using channel (narrowband) filtering, analog impairment conditioning (such as correcting for I/Q imbalance), and applying digital gain to ultimately obtain a narrowband signal. The output of the DSP circuitry may be fed to the AGC, which is configured to use information extracted from the digital signals, for example, in one or more received training fields, to determine an appropriate gain. The output of the DSP circuitry also may be coupled with the demodulator, which is configured to extract modulated symbols from the signal and, for example, compute the logarithm likelihood ratios (LLRs) for each bit position of each subcarrier in each spatial stream. The demodulator may be coupled with the decoder, which may be configured to process the LLRs to provide decoded bits. The decoded bits from all of the spatial streams may be fed to the demultiplexer for demultiplexing. The demultiplexed bits may be descrambled and provided to a medium access control layer (e.g., the processor 212) for processing, evaluation, or interpretation.

In certain aspects, the RF transceiver 250 may include the noise source circuit 106 of FIG. 1. As an example, the noise source circuit 106 may be coupled to the TX path 218 at the input port of the PA 230, such that the noise source circuit 106 may feed noise to the PA 230 to enable a noise figure characterization of the PA 230 as further described herein. As another example, the noise source circuit 106 may be coupled to the RX path 222 at the input port of the LNA 232, such that the noise source circuit 106 may feed noise to the LNA 232 to enable a noise figure characterization of the LNA 232 as further described herein. Note that the termination points of the noise source circuit 106 at the input ports of the PA 230 and the LNA 232, respectively, are merely examples to facilitate an understanding of noise figure characterization via an on-chip noise source. Aspects of the present disclosure may be applied to alternative or additional termination(s) for the noise source circuit to feed noise to component(s) of the RF transceiver 250, such as the input port(s) of the BBF 226, 236; the mixer 228, 234; the frequency synthesizer 240; and/or the interface 224.

The modem 210 and/or processor 212 may control the transmission of signals via the TX path 218 and/or reception of signals via the RX path 222. In some aspects, the modem 210 and/or processor 212 may be configured to perform various operations, such as those associated with any of the methods described herein. The modem 210 and/or processor 212 may include a microcontroller, a microprocessor, an application processor, a baseband processor, a MAC processor, an artificial intelligence (AI) processor, a digital signal processor (DSP), an application specific integrated circuit (ASIC), a field programmable gate array (FPGA) or other programmable logic device (PLD), discrete gate or transistor logic, discrete hardware components, or any combination thereof. The memory 214 may store data and program codes (e.g., processor-readable instructions) for performing wireless communications as described herein. In some cases, the memory 214 may be external to the modem 210 and/or processor 212 and/or incorporated therein (as illustrated with the memory 214 or being incorporated with the processor 212).

FIG. 2 shows an example transceiver design. It will be appreciated that other transceiver designs or architectures may be applied in connection with aspects of the present disclosure. For example, while examples discussed herein utilize I and Q signals (e.g., quadrature modulation), those of skill in the art will understand that components of the transceiver may be configured to utilize any other suitable modulation, such as polar modulation. As another example, circuit blocks may be arranged differently from the configuration shown in FIG. 2, and/or other circuit blocks not shown in FIG. 2 may be implemented in addition to or instead of the blocks depicted. For example, it will be understood by those skilled in the art that certain details of a wireless device are omitted from FIG. 2 for ease of illustration.

### Example On-Chip Noise Source

Aspects of the present disclosure provide apparatuses and methods for an on-chip noise source that may enable dynamic, accurate, and/or reliable noise figure measurements.

FIG. 3 depicts an example architecture 300 for in situ noise figure characterization of a signal chain. In this example, the architecture may include a transceiver package 302 coupled to (or in communication with) one or more processors (hereinafter “the processor 304”). The processor 304 may be coupled to one or more memories (hereinafter “the memory 306”). The processor 304 may be an example of the modem 210 and/or the processor 212 of FIG. 2. The memory 306 may be an example of the memory 214 of FIG. 2.

The transceiver package 302 may include a noise source circuit 308 and a signal chain 310. The transceiver package 302 may be a circuit package that includes an RF transceiver, such as an RF front end module, an RF transceiver circuit, or the like. The circuit package may be any suitable circuit assembly, such as a circuit board, a motherboard, a mainboard, a chip, a chipset, a SoC, a SiP, an integrated circuit, or the like. In certain aspects, the transceiver package may include the RF transceiver 250 of FIG. 2 or a portion thereof.

The signal chain 310 may be an example of the TX path 218, the RX path 222, and/or one or more components thereof (such as the PA 230 or the LNA 232), for example, as described herein with respect to FIG. 2. The signal chain 310 may include one or more mixers (e.g., the mixer 228, 234) coupled to one or more amplifiers (e.g., the PA 230 and/or the LNA 232). As an example, the signal chain 310 may include a receive chain configured to receive an RF signal; and the noise source circuit 308 may be configured to feed the noise to amplifier(s) of the signal chain, such as the LNA 232. As another example, the signal chain 310 may include a transmit chain configured to transmit an RF signal; and the noise source circuit 308 may be configured to feed noise to mixer(s) of the signal chain, such as the mixer 228.

The in situ noise figure characterization described herein may characterize the noise figure associated with the signal chain and/or one or more component thereof. The in situ noise figure characterization may enable dynamic, accurate, and/or reliable noise figure measurements associated with the signal chain. In certain cases, the noise figure characterization may be performed throughout the operating life of the signal chain to enable compensation for changes in the noise figure of the signal chain. In certain cases, the in situ noise figure characterization may allow for improved accuracy and/or reliability of the noise figure measurements, for example, by enabling a consistent output impedance for cold state and hot state measurements.

The noise source circuit 308 may be or include an amplifier-based noise circuit and/or a current-mode noise circuit, for example, as further described herein with respect FIGS. 4 and 5, respectively. The noise source circuit 308 may be an example of the noise source circuit 106 of FIGS. 1 and 2. The noise source circuit 308 may be selectively coupled to the signal chain 310, via a switch 312, to allow for the noise source circuit 308 to be disabled, for example, when the signal chain 310 is used for wireless communications.

During certain operations of noise figure characterization, the noise source circuit 308 may feed noise to the signal chain 310 at different power levels, for example, to characterize the noise added or generated by the signal chain 310 at a plurality of states, such as a cold state and a hot state, associated with the noise source circuit 308. The cold state and the hot state may refer to the noise temperatures used to determine the noise figure as part of a Y-factor method. The noise temperature is a way to express the noise of a system (such as, the noise source circuit 308) in terms of temperature, for example, due to the noise power being proportional to the temperature. The noise temperature is the equivalent temperature of the noise power per unit bandwidth of an active or passive system (e.g., the noise source) at any given frequency.

The Y-factor method is a technique for determining the noise figure of a circuit (e.g., the signal chain) through measurements of the output power of the circuit when the input of the circuit is terminated by loads (e.g., the noise source circuit 308) at different noise temperatures, such as a high noise temperature (e.g., the hot state) and a cold noise temperature (e.g., the cold state or ambient state). The cold state may refer to a state of the noise source circuit 308 (e.g., the load seen or terminated at the input of the signal chain) operating at a first temperature (e.g., an ambient temperature), and the hot state may refer to another state of the noise source circuit 308 operating at a second temperature different than the first temperature (e.g., higher than the first temperature).

As an example, the Y-factor associated with the signal chain 310 may be based on the hot state output power and the cold state output power, for example, given by the following:

$$Y = \frac{{P}_{out \_ hot}}{{P}_{out \_ cold}} \qquad ( 1 )$$

where P_{out_cold} is the output power of the signal chain 310 when the noise source circuit 308 feeds noise, to the signal chain 310, at the power level associated with the cold state; and P_{out_hot} is the output power of the signal chain 310 when the noise source circuit 308 feeds noise, to the signal chain 310, at the power level associated with the hot state. The noise figure (NF) associated with the signal chain 310 may be based on the Y-factor and the excess noise ratio (ENR) associated with the noise source circuit 308, for example, given by the following:

$$NF = \frac{ENR}{Y - 1} \qquad ( 2 )$$

where ENR is the excess noise ratio (ENR) of the noise source circuit 308. The ENR may be determined through calibration, simulations, and/or estimations of the noise source circuit 308. Note that the Y-factor method is an example technique for determining the noise figure associated with the signal chain 310. Aspects of the present disclosure may apply additional or alternative techniques to determine the noise figure associated with the signal chain 310.

The processor 304 may be coupled to or in communication with the transceiver package 302 to control the operations to measure the noise figure associated with the signal chain 310. As an example, the processor 304 may configure the noise source circuit 308 to operate in the cold state and the hot state. In certain cases, the processor 304 may obtain or determine characteristics associated with the signal chain 310 based on the noise fed to the signal chain 310 at the noise temperature states of the noise source circuit 308 (e.g., the cold state and hot state). The processor may perform or implement the operations of the noise source manager 242 of FIG. 2.

In certain aspects, the noise source circuit 308 may feed, to the signal chain 310 at a first time occasion, first noise at a first power level associated with a first state (e.g., the cold state). The noise source circuit 308 may feed, to the signal chain 310 at a second time occasion, second noise at a second power level associated with a second state (e.g., the hot state). At the first time occasion and the second time occasion, the noise source circuit may be configured to apply the same (e.g., a consistent) output impedance and ENR, which may be enabled using the noise circuit architecture(s) described herein.

The processor 304 may determine or obtain a first output power of the signal chain 310 based on the first noise fed at the first power level (e.g., P_{out_cold}). The processor 304 may determine or obtain a second output power of the signal chain 310 based on the second noise fed at the second power level (e.g., P_{out_hot}). The processor 304 may determine a noise figure associated with the signal chain 310 based at least in part on a comparison of the first output power and the second output power, for example, according to Expressions (1) and (2).

In certain cases, the noise fed to the signal chain 310 via the noise source circuit 308 may be swept across a range of frequencies, for example, at the cold state and the hot state. In certain cases, the noise fed to the signal chain 310 via the noise source circuit 308 may occupy one or more frequencies and/or one or more frequency bandwidths, for example, at the cold state and the hot state.

Note that the transceiver package 302 is merely an example circuit package to facilitate an understanding of in situ noise figure characterization. Aspects of the present disclosure may apply to other circuit packages that include an on-chip noise source, such as the noise source circuit 308, for in situ noise figure characterization.

FIG. 4 depicts an example architecture of an amplifier-based noise source circuit (hereinafter “the noise source circuit 400”). The noise source circuit 400 may be an example of the noise source circuit 106 of FIGS. 1 and 2 and/or the noise source circuit 308 of FIG. 3.

In this example, the noise source circuit 400 may include a noise generator circuit 402 and an amplifier circuit 404 coupled to the noise generator circuit 402. The noise source circuit 400 may be configured to generate noise across a range of frequencies, and in some cases, higher frequencies than the current-mode noise source circuit described herein with respect to FIG. 5. As an example, the noise source circuit 400 may be configured to generate noise at up to 7.25 GHz and/or in millimeter wave frequency bands (e.g., 24.25 GHz to 71.0 GHz) with a suitable ENR (such as 6 dB-15 dB) for the cold state and hot state.

The noise generator circuit 402 may output noise within a range of frequencies (e.g., 600 MHz-7.25 GHz or higher). In certain cases, the noise generator circuit 402 may generate thermal electrical noise in a specific frequency band (e.g., the range of frequencies). In certain cases, the thermal electrical noise may be or include white noise in the frequency band. The noise generator circuit 402 may be coupled to the amplifier circuit 404, such that the noise generator circuit 402 feeds the noise to an input port of the amplifier circuit 404. The noise generator circuit 402 may include an inverter topology. In certain cases, the inverter topology may include one or more inverters, such as a complementary metal oxide semiconductor (CMOS) inverter. In certain aspects, the noise generator circuit 402 may include a diode coupled inverter, for example, including a p-channel diode coupled to an n-channel diode, as further described herein. The diode-coupled inverter may generate a white thermal noise. Note that the noise generator circuit shown in FIG. 4 is merely an example, and additional or alterative noise generator(s) may be used, such as additional diode coupled CMOS inverter(s).

As an example, the noise generator circuit 402 may include a first output node 406, a first transistor 408, and a second transistor 410. The first transistor 408 may be or include a p-channel metal oxide semiconductor (PMOS) transistor; and the second transistor 410 may be or include an n-channel MOS (NMOS) transistor. The first transistor 408 includes a drain coupled to the first output node 406; and the second transistor 410 includes a drain coupled to the first output node 406. The gates of the first transistor 408 and the second transistor 410 may be coupled to the first output node 406, for example, via a feedback path (represented as the resistor R_{F}). With the drains coupled to the gates, the first transistor 408 and the second transistor 410 may behave as diodes. The source of the first transistor 408 may be coupled to a first reference node (e.g., a supply voltage Vdd or bias voltage); and the source of the second transistor 410 may be coupled to a second reference node (e.g., a circuit ground or a circuit reference potential). With the drains coupled to the gates, the first transistor 408 and the second transistor 410 may behave as diodes. Thus, the noise generator circuit 402 may be referred to as a diode coupled inverter.

The amplifier circuit 404 may amplify the noise generated by or at the noise generator circuit 402 and feed the amplified noise to a signal chain (such as the signal chain 310). The amplifier circuit 404 may amplify the noise using different power levels for the cold state and the hot state, as described herein. The amplifier circuit 404 may be configured to have a particular output impedance (e.g., 50 Ohms (Ω) at the cold state and the hot state, as described herein. The amplifier circuit 404 may include an inverter topology, which may include a CMOS transistor topology.

As an example, the amplifier circuit 404 may include a second output node 412, a third transistor 414, and a fourth transistor 416. The third transistor 414 may be or include a PMOS transistor; and the fourth transistor 416 may be or include an NMOS transistor. The third transistor 414 includes a gate coupled to the first output node 406 and a drain coupled to the second output node 412; and the fourth transistor 416 includes a gate coupled to the first output node 406 and a drain coupled to the second output node 412. The source of the third transistor 414 may be coupled to the first reference node (e.g., a supply voltage Vdd); and the source of the fourth transistor 416 may be coupled to the second reference node (e.g., a circuit ground or circuit reference potential). The amplifier circuit 404 may feed noise to the signal chain via the second output node 412. In this example, the second output node 412 is a common-mode node coupled between common-mode resistors. In certain aspects, the amplifier circuit 404 may be configured to output balanced or differential noise.

As an example, the output noise power at certain frequencies (e.g., <2.4 GHz) of the noise source circuit 400 may be expressed as follows:

$${V}_{A M} = 4 k T γ ( 2 {g}_{m 2} ) {R}_{s}^{2} ( 1 + {g}_{m 1} {g}_{m 2} {r}_{o 1}^{2} ) \qquad ( 3 )$$

where k is Boltzmann constant; T is the temperature of the transistor; γ is the white noise gamma factor or excess noise coefficient associated with the transistors; gₘ₁ and gₘ₂ are the output transconductances of the noise generator circuit 402 and the amplifier circuit 404, respectively; R_{S} is the base resistance of the common-mode resistors (e.g., 2R_{S}); and rₒ₁ is the overall resistance of the noise source circuit 400. Note that the AM may denote “amplifier mode.”

The dominant pole of the noise source circuit 400 may be based on at the output of the first stage, for example, given by the following:

$${P}_{A M} = \frac{1}{{r}_{o 1} {C}_{o}} \qquad ( 4 )$$

where Cₒ is the overall capacitance of the noise generator circuit 402.

Accordingly, the noise source circuit 400 may enable in situ noise figure characterization across a wide bandwidth of frequencies, for example, up to 7.25 GHz or higher (such as millimeter wave frequency bands).

FIG. 5 depicts an example architecture of a current-mode noise source circuit (hereinafter “the noise source circuit 500”), such as a current-mirror-based noise circuit. The noise source circuit 500 may be an example of the noise source circuit 106 of FIGS. 1 and 2 and/or the noise source circuit 308 of FIG. 3.

In this example, the noise source circuit 500 may be configured to feed noise to a signal chain (e.g., the signal chain 310 of FIG. 3). The noise source circuit 500 may include an output node 502, an inverter circuit 504, a current-mirror circuit 506, an amplifier circuit 508, a current-sink circuit 510, and a variable resistive element 512. In certain cases, the noise source circuit 500 may include a current source circuit 514, for example, in a common-mode or single-ended architecture, as depicted.

The inverter circuit 504 may include a CMOS inverter to output a balanced or differential control signal, which may be used to activate or deactivate the noise source circuit 500. In certain cases, the inverter circuit 504 may include an inverter topology, such as the inverter topology described herein with respect to FIG. 4. The inverter circuit 504 may be configured to output a differential control signal having a first control signal (e.g., EN) and a second control signal (e.g., E̅N̅). The second control signal may be the first control signal but of opposite polarity. Accordingly, the first control signal and the second control signal may represent and be referred to as balanced control signaling.

The current-mirror circuit 506 may include a transistor-based current mirror, such as an NMOS transistor (e.g., M₂). As a current-mirror, the gate of M₂ may be coupled to the drain of M₂. The current-mirror circuit 506 may include another NMOS transistor (e.g., M₄) coupled to an input stage of the amplifier circuit 508. A switch may be coupled between the gate of M₂ and the input stage of the amplifier circuit 508. The first control signal may be fed to the switch, and the second control signal may be fed to the gate of M₄, such that when the switch is closed, M₄ is effectively disabled (e.g., M₄ behaves as an open switch); and when the switch is open, M₄ is effectively enabled (e.g., M₄ behaves as a closed switch). The current-mirror circuit 506 may drive or regulate the electrical noise fed to the amplifier circuit 508 in a current-mode.

The drain current of M₂ may be supplied by Vdd through resistor R_{B}, where the current through resistor R_{B} may be considered the reference current of the current-mirror circuit 506. Assuming M₂ and M₁ are operating in saturation, the effective output current (e.g., IDI, the drain current of M₁) may be based in part on the geometries of M₂ and M₁, such as the channel widths. For example, the drain current of M₁ may be related to the reference current of the current-mirror circuit 506 by the ratio of the aspect ratios of M₂ and M₁.

The amplifier circuit 508 may be coupled to the output node 502 and the current-mirror circuit 506. The amplifier circuit 508 may be configured to amplify the noise fed, to the input stage of the amplifier circuit 508, by the current-mirror circuit 506. The amplifier circuit 508 may include a cascode transistor topology, for example, including a first NMOS transistor (e.g., M₁) coupled to a second NMOS transistor (e.g., M₃). In certain cases, the cascode transistor topology may include two or more stages of cascode transistors. The amplifier circuit 508 may include a switch circuit coupled to the gate of M₃, where the switch circuit includes a first switch coupled to Vdd and a second switch coupled to a circuit ground. The inverter circuit 504 may feed the balanced control signaling (EN and E̅N̅) to the first switch and the second switch, as depicted, such that M₃ may be enabled or disabled according to the polarities of the first control signal and the second control signal.

The current-sink circuit 510 may be configured to regulate the electrical current that passes through the amplifier circuit 508 at the cold state and/or the hot state, for example, to reduce or prevent M₁, M₂, and/or M₃ from being driven into the triode region (or ensure M₁, M₂, and/or M₃ are operating in saturation). The current-sink circuit 510 may be coupled to the output node 502 and the current-mirror circuit 506. The current-sink circuit 510 may be coupled in parallel with the amplifier circuit 508. The current-sink circuit 510 may be activated during the cold state and the hot state measurements, for example, to enable a consistent and high ENR of the noise source circuit 500 (such as an ENR of 6 dB-15 dB). Thus, the current-sink circuit 510 may enable the current-mode noise source circuit 500 to have a suitable output noise power in the cold state. The current-sink circuit 510 may generally have the same cascode transistor topology and transistor aspect ratios of the amplifier circuit 508, for example, including a first NMOS transistor (e.g.,

$${M}_{1}^{′} )$$

coupled to a second MOS transistor (e.g.,

$${M}_{3}^{′} ) .$$

The gate of

$${M}_{1}^{′}$$

may be coupled to the gate of M₂; the gate of

$${M}_{3}^{′}$$

may be coupled to Vdd; and the drain of

$${M}_{3}^{′}$$

may be coupled to the output node 502.

The variable resistive element 512 (e.g., R_{D}) may enable adjustment of the output impedance (e.g., 50Ω) as seen at the output node 502 or terminated at the input of the signal chain for the cold state and the hot state. As an example, the resistance of the variable resistive element 512 may be adjusted to a specific value depending on the power level (or ENR) of the cold state or the hot state used for the noise figure measurements. In certain cases, the variable resistive element 512 may be adjusted to a resistance value based on the processor corner(s) used to fabricate the transistors (e.g., M₁, M₂, M₃, etc.), for example, using an on-chip process control monitor (PCM). Thus, the variable resistive element 512 may mitigate or reduce load variations due to the process corners of the noise source circuit 500.

The variable resistive element 512 may be coupled between the output node 502 and a supply voltage (e.g., Vdd). The variable resistive element 512 may include a digital potentiometer, which may have a resistance resolution of 2Ω per least significant bit to tune the output impedance to a specific value (e.g., 50Ω). In certain cases, the variable resistive element 512 may include a selective resistor ladder, for example, including a plurality or resistors arranged in a series network, where each resistor of the resistor ladder has a switch coupled to a bypass path.

For a common-mode or single-ended architecture (as shown), the current source circuit 514 may be used to regulate the current that passes through the variable resistive element 512, for example, to reduce or prevent M₁, M₂, and/or M₃ from being driven into triode (or ensure M₁, M₂, and/or M₃ are operating in saturation). In certain aspects, the current source circuit 514 may regulate the current that passes through the variable resistive element 512 to satisfy a threshold transconductance and/or a threshold ENR without reducing the output impedance of the noise source circuit 500 in the hot state. The current source circuit 514 may include PMOS transistors to work with the small voltage headroom.

In certain cases, the noise source circuit 500 may be arranged in a balanced, differential, or complementary architecture (hereinafter the balanced architecture) having a complementary semiconductor architecture that includes PMOS transistors. The variable resistive element 512 may be arranged as a common-mode resistor, for example, the resistors (2R_{S}) depicted in FIG. 4. For the balanced architecture, the current-mode noise source circuit may not include the current source circuit 514. The balanced architecture may increase the output noise power by a factor of two compared to a single-ended architecture, as depicted in FIG. 5. In certain cases, the balanced architecture may enable the transconductance of the current-mode noise source circuit to be relaxed.

The output noise power of the noise source circuit at certain frequencies (e.g., <2.4 GHz) may be expressed as follows:

$${V}_{C M} = 4 k T γ {g}_{m 1} ( 1 + \frac{{W}_{1}}{{W}_{2}} ) {R}_{s}^{2} \qquad ( 5 )$$

where gₘ₁ is the output tranconductance of the noise source circuit 500; W₁ is the channel width of M₁ (and/or

$${M}_{1}^{′}$$

), W₂ is the channel width of M₂; and Rₛ is the base resistance of the common-mode resistors (e.g., 2R_{S}=R_{D}). Note that CM may denote “current mode” or “current mirror.”

In certain aspects, the ENR of the noise source circuit 500 may be based at least in part on the aspect ratios of certain transistors (e.g., M₁ and M₂), for example, according to the current transfer ratio associated with M₁ and M₂. The ENR associated with the current-mode noise source circuit 500 may depend at least in part on a first channel width of a first transistor of the current-mirror circuit 506 (e.g., M₂) and a second channel width of a second transistor of the amplifier circuit 508 (e.g., M₁ or M₁′). For example, the ENR may be given by the following:

$$ENR = γ {g}_{m 1} ( 1 + \frac{{W}_{1}}{{W}_{2}} ) {R}_{s} \qquad ( 6 )$$

In certain aspects, the effective transconductance of the noise source circuit 500 may be boosted by a factor of W₁/W₂. Therefore, to achieve high ENR, the transconductance can be drastically reduced as long as W₁ is much larger than W₂. For instance, for an ENR of 15 dB, using a sizing ratio of W₁/W₂=15 results in a transconductance as follows:

$${g}_{m 1} = \frac{ENR}{γ {R}_{s} ( 1 + \frac{{W}_{1}}{{W}_{2}} )} = \frac{31.5}{1 \times 50 \times 16} = 39.4 mS \qquad ( 7 )$$

Therefore, at low frequencies (e.g., <2.4 GHz), the noise source circuit 500 may use reduced the power consumption and/or chip area, due in part to the current transfer ratio between M₁ and M₂.

At high frequencies (e.g., >2.4 GHZ), the ENR may be impacted by the pole of the mirroring node. The dominant pole of the noise source circuit 500 may be given by the following:

$${P}_{CM} = \frac{{g}_{m 2}}{{C}_{p}} \qquad ( 8 )$$

where Cₚ is the parasitic capacitance at the mirroring node. Thus, at high frequencies (e.g., >2.4 GHz), the dominant pole may drown out any gains to the ENR attributable to adjusting the aspect ratios of M₁ and M₂, such as the channel widths of W₁ and W₂. For example, increasing W₁ and decreasing W₂ reduces the frequency of the dominant pole by increasing Cₚ (which is dominated by parasitics of M₁ due to the increased size of M₁) and decreasing gₘ₂, respectively.

Accordingly, the variable resistive element 512 and the current-sink circuit 510 may enable the noise source circuit 500 to reduce any errors (e.g., improve the accuracy and/or reliability), associated with the noise output power at the cold state and hot state, in noise figure measurements to negligible levels while maintaining a high ENR.

A figure-of-merit (FoM) may be used to compare the performance of the amplifier-based noise source circuit 400 and the current-mode noise source circuit 500. The FoM may be defined as a product of the low-frequency noise power level and the dominant pole frequency associated with the respective noise source circuits. As an example, the FoM may be given as follows:

$$\frac{{FoM}_{AM}}{{FoM}_{CM}} = \frac{{V}_{AM} {P}_{AM}}{{V}_{CM} {P}_{CM}} = \frac{{C}_{p}}{{C}_{o}} \times \frac{{g}_{m 2 \vert AM}^{2}}{{g}_{m 2 \vert CM}^{2}} \times 2 {g}_{m 1 \vert AM} {r}_{o 1}$$

Assuming the amplifier-based and the current-mode noise sources have equal sizing, current, and transconductance, the FoM demonstrates that the amplifier-based noise source has a higher FoM by a factor of 2g_{m1|AM}rₒ₁. Accordingly, the amplifier-based noise source circuit may enable dynamic, accurate, and/or reliable in situ noise figure characterization.

### Example Operations of Noise Figure Characterization

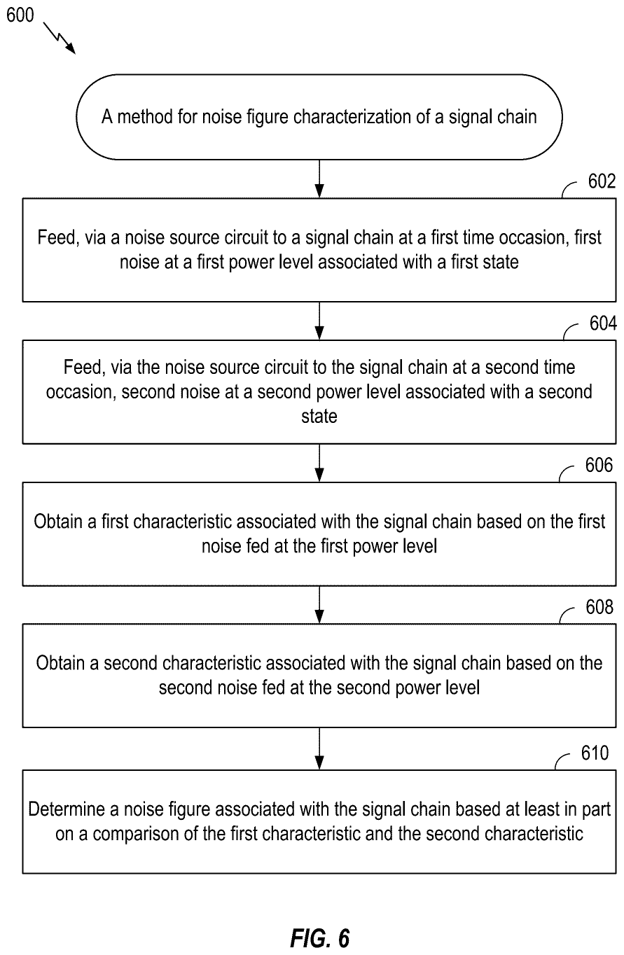

FIG. 6 illustrates example operations 600 for in situ noise figure characterization of a signal chain. The operations 600 may be performed, for example, by a wireless device (e.g., the first wireless device 102 in the wireless communications system 100). The operations 600 may be implemented as software components that are executed and run on one or more processors (e.g., the modem 210 and/or the processor 212 of FIG. 2). Further, the transmission and/or reception of signals by the wireless device in the operations 600 may be enabled, for example, by one or more antennas (e.g., the antenna 220 of FIG. 2). In certain aspects, the transmission and/or reception of signals by the wireless device may be implemented via a bus interface of one or more processors (e.g., the modem 210 and/or the processor 212 of FIG. 2) obtaining and/or outputting signals for reception or transmission.

The operations 600 may optionally begin, at block 602, where the wireless device may feed, via a noise source circuit to a signal chain at a first time occasion, first noise at a first power level associated with a first state (e.g., the cold state), for example, as described herein with respect to FIGS. 2-5. The signal chain comprises one or more mixers coupled to one or more amplifiers, for example, as described herein with respect to FIGS. 2 and 3. The wireless device may include transceiver package including the signal chain and the noise source circuit. The noise source circuit may be any of the noise source circuits described herein with respect to FIGS. 3-5. In certain cases, the noise source circuit may include an amplifier-based noise source circuit. As an example, the noise source circuit may include a noise generator circuit and an amplifier circuit, for example, as described herein with respect to FIG. 4. In certain cases, the noise source circuit may include a current-mode noise source circuit, for example, as described herein with respect to FIG. 5. As an example, the noise source circuit may include an output node, a noise generator circuit, a current-mirror circuit, a current-sink circuit, and a variable resistive element.

At block 604, the wireless device may feed, via the noise source circuit to the signal chain at a second time occasion, second noise at a second power level associated with a second state (e.g., the hot state).

At block 606, the wireless device may obtain a first characteristic associated with the signal chain based on the first noise fed at the first power level.

At block 608, the wireless device may obtain a second characteristic associated with the signal chain based on the second noise fed at the second power level.

At block 610, the wireless device may determine a noise figure associated with the signal chain based at least in part on a comparison of the first characteristic (e.g., Pout_cold) and the second characteristic (e.g., Pout_hot), for example, according to Expression (2).

In certain aspects, feeding the first noise comprises feeding, via the noise generator circuit to the amplifier circuit, third first noise within a range of frequencies. In certain aspects, feeding the first noise comprises: amplifying the third noise via the amplifier circuit; and feeding, via the amplifier circuit, the amplified third noise to the signal chain, wherein the first noise comprises the amplified third noise.

In certain aspects, feeding the first noise comprises feeding the first noise to the one or more amplifiers.

In certain aspects, feeding the first noise comprises feeding the first noise to the one or more mixers.

In certain aspects, feeding the first noise comprises regulating electrical current, through the amplifier circuit, via the current-sink circuit, for example, as described herein with respect to FIG. 5.

Aspects of the present disclosure may be applied to any of various wireless communication devices that may perform in situ noise figure characterization, such as a portable wireless communication device, UE, base station, access point, and/or CPE.

Various components described herein may provide means for performing the operations 600 described with respect to FIG. 6, or any aspect related to operations described herein. For example, means for feeding noise may include the noise source circuit 308, 400, 500 of FIGS. 3-5. Means for obtaining and/or means for determining may include one or more processors, such as the modem 210 and/or processor 212 depicted in FIG. 2 and/or the processor(s) 304 in FIG. 3.

### EXAMPLE ASPECTS

Implementation examples are described in the following numbered clauses:
Aspect 1: A radio frequency (RF) circuit, comprising: a transceiver package comprising: a signal chain comprising one or more mixers coupled to one or more amplifiers; and a noise source circuit coupled to the signal chain, the noise source circuit comprising: a noise generator circuit comprising a first inverter topology, wherein the noise generator circuit is configured to output noise within a range of frequencies; and an amplifier circuit comprising a second inverter topology, wherein the amplifier circuit is coupled to the noise generator circuit, wherein the amplifier circuit is configured to amplify the noise and feed the amplified noise to the signal chain.
Aspect 2: The RF circuit of Aspect 1, wherein the first inverter topology comprises a complementary metal oxide semiconductor (CMOS) transistor topology.
Aspect 3: The RF circuit of Aspect 1 or 2, wherein the first inverter topology comprises a diode-coupled inverter.
Aspect 4: The RF circuit according to any of Aspects 1-3, wherein the second inverter topology comprises a complementary metal oxide semiconductor (CMOS) transistor topology.
Aspect 5: The RF circuit according to any of Aspects 1-4, wherein: the noise generator circuit comprises: a first output node; a first transistor including a drain coupled to the first output node; and a second transistor including a drain coupled to the first output node; and the amplifier circuit comprises: a second output node; a third transistor including a gate coupled to the first output node and a drain coupled to the second output node; and a fourth transistor including a gate coupled to the first output node and a drain coupled to the second output node.
Aspect 6: The RF circuit according to any of Aspects 1-5, further comprising one or more memories; and one or more processors coupled to the one or more memories, wherein: the one or more processors are configured to cause the noise source circuit to: feed, to the signal chain at a first time occasion, first noise at a first power level associated with a first state; and feed, to the signal chain at a second time occasion, second noise at a second power level associated with a second state.
Aspect 7: The RF circuit of Aspect 6, wherein the one or more processors are configured to: obtain a first characteristic associated with the signal chain based on the first noise fed at the first power level; obtain a second characteristic associated with the signal chain based on the second noise fed at the second power level; and determine a noise figure associated with the signal chain based at least in part on a comparison of the first characteristic and the second characteristic.
Aspect 8: The RF circuit according to any of Aspects 1-7, wherein: the signal chain comprises a receive chain configured to receive an RF signal; and the noise generator circuit is configured to feed the amplified noise to the one or more amplifiers.
Aspect 9: The RF circuit according to any of Aspects 1-8, wherein: the signal chain comprises a transmit chain configured to transmit an RF signal; and the noise generator circuit is configured to feed the amplified noise to the one or more mixers.
Aspect 10: A radio frequency (RF) circuit, comprising: a transceiver package comprising: a signal chain comprising one or more mixers coupled to one or more amplifiers; and a current-mode noise source circuit coupled to the signal chain, wherein the current-mode noise source circuit is configured to feed noise to the signal chain, the current-mode noise source circuit comprising: an output node; a current-mirror circuit; an amplifier circuit coupled to the output node and the current-mirror circuit; a current-sink circuit coupled to the output node and the current-mirror circuit; and a variable resistive element coupled to the output node.
Aspect 11: The RF circuit of Aspect 10, wherein the current-mode noise source circuit further comprises an inverter circuit configured to output balanced control signaling.
Aspect 12: The RF circuit of Aspect 11, wherein the amplifier circuit comprises: a cascode transistor topology; and a switch circuit coupled to a gate of a transistor of the cascode transistor topology, wherein the inverter circuit is configured to feed the balanced control signaling to the switch circuit.
Aspect 13: The RF circuit according to any of Aspects 10-12, wherein the current-sink circuit comprises a cascode transistor topology.
Aspect 14: The RF circuit according to any of Aspects 10-13, wherein the variable resistive element comprises a digital potentiometer.
Aspect 15: The RF circuit according to any of Aspects 10-14, wherein an excess noise ratio associated with the current-mode noise source circuit depends at least in part on a first channel width of a first transistor of the current-mirror circuit and a second channel width of a second transistor of the amplifier circuit.
Aspect 16: The RF circuit according to any of Aspects 10-15, further comprising one or more memories; and one or more processors coupled to the one or more memories, wherein the one or more processors are configured to cause the current-mode noise source circuit to: feed, to the signal chain at a first time occasion, first noise at a first power level associated with a first state; and feed, to the signal chain at a second time occasion, second noise at a second power level associated with a second state.
Aspect 17: The RF circuit of Aspect 16, wherein the one or more processors are configured to: obtain a first characteristic associated with the signal chain based on the first noise fed at the first power level; obtain a second characteristic associated with the signal chain based on the second noise fed at the second power level; and determine a noise figure associated with the signal chain based at least in part on a comparison of the first characteristic and the second characteristic.
Aspect 18: The RF circuit according to any of Aspects 10-17, wherein: the signal chain comprises a receive chain configured to receive an RF signal; and the current-mode noise source circuit is configured to feed the noise to the one or more amplifiers.
Aspect 19: The RF circuit according to any of Aspects 10-18, wherein: the signal chain comprises a transmit chain configured to transmit an RF signal; and the current-mode noise source circuit is configured to feed the noise to the one or more mixers.
Aspect 20: A method for noise figure characterization of a signal chain, comprising: feeding, via a noise source circuit to a signal chain at a first time occasion, first noise at a first power level associated with a first state, wherein a transceiver package comprises the signal chain and the noise source circuit, wherein the signal chain comprises one or more mixers coupled to one or more amplifiers, wherein the noise source circuit comprises a noise generator circuit and an amplifier circuit; feeding, via the noise source circuit to the signal chain at a second time occasion, second noise at a second power level associated with a second state; obtaining a first characteristic associated with the signal chain based on the first noise fed at the first power level; obtaining a second characteristic associated with the signal chain based on the second noise fed at the second power level; and determining a noise figure associated with the signal chain based at least in part on a comparison of the first characteristic and the second characteristic.
Aspect 21: The method of Aspect 20, wherein feeding the first noise comprises feeding, via the noise generator circuit to the amplifier circuit, third first noise within a range of frequencies.
Aspect 22: The method of Aspect 21, wherein feeding the first noise comprises: amplifying third noise via the amplifier circuit; and feeding, via the amplifier circuit, the amplified third noise to the signal chain, wherein the first noise comprises the amplified third noise.
Aspect 23: The method according to any of Aspects 20-22, wherein feeding the first noise comprises feeding the first noise to the one or more amplifiers.
Aspect 24: The method according to any of Aspects 20-23, wherein feeding the first noise comprises feeding the first noise to the one or more mixers.
Aspect 25: A method for noise figure characterization of a signal chain, comprising: feeding, via a noise source circuit to a signal chain at a first time occasion, first noise at a first power level associated with a first state, wherein a transceiver package comprises the signal chain and the noise source circuit, wherein the signal chain comprises one or more mixers coupled to one or more amplifiers, wherein the noise source circuit comprises an output node, a noise generator circuit, a current-mirror circuit, an amplifier circuit, a current-sink circuit, a variable resistive element; feeding, via the noise source circuit to the signal chain at a second time occasion, second noise at a second power level associated with a second state; obtaining a first characteristic associated with the signal chain based on the first noise fed at the first power level; obtaining a second characteristic associated with the signal chain based on the second noise fed at the second power level; and determining a noise figure associated with the signal chain based at least in part on a comparison of the first characteristic and the second characteristic.
Aspect 26: The method of Aspect 25, wherein feeding the first noise comprises regulating electrical current, through the amplifier circuit, via the current-sink circuit.
Aspect 27: The method of Aspect 25 or 26, wherein feeding the first noise comprises feeding the first noise to the one or more amplifiers.
Aspect 28: The method according to any of Aspects 25-27, wherein feeding the first noise comprises feeding the first noise to the one or more mixers.
Aspect 29: An apparatus, comprising: a memory; and one or more processors configured to perform a method in accordance with any of Aspects 20-28.
Aspect 30: An apparatus, comprising means for performing a method in accordance with any of Aspects 20-28.
Aspect 31: A non-transitory computer-readable medium comprising computer-executable instructions that, when executed by one or more processors of a processing system, cause the processing system to perform a method in accordance with any of Aspects 20-28.
Aspect 32: A computer program product embodied on a computer-readable storage medium comprising code for performing a method in accordance with any of Aspects 20-28.
Aspect 33: A method of manufacturing an apparatus, comprising making a radio frequency circuit in accordance with any of Aspects 1-19.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a microcontroller, a microprocessor, a general purpose processor, an artificial intelligence (AI) processor, a digital signal processor (DSP), an ASIC, a field programmable gate array (FPGA) or other programmable logic device (PLD), discrete gate or transistor logic, discrete hardware components, or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), a system in package (SiP), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and or like. Also, “determining” may include receiving (e.g., receiving information), accessing (e.g., accessing data in a memory) or the like. Also, “determining” may include resolving, selecting, choosing, establishing or the like.

As used herein, “coupled to” and “coupled with” generally encompass direct coupling and indirect coupling (e.g., including intermediary coupled aspects) unless stated otherwise. For example, stating that a processor is coupled to a memory allows for a direct coupling or a coupling via an intermediary aspect, such as a bus.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Reference to an element in the singular is not intended to mean only one unless specifically so stated, but rather “one or more.” The subsequent use of a definite article (e.g., “the” or “said”) with an element (e.g., “the processor”) is not intended to invoke a singular meaning (e.g., “only one”) on the element unless otherwise specifically stated. For example, reference to an element (e.g., “a processor,” “a controller,” “a memory,” “a transceiver,” “an antenna,” “the processor,” “the controller,” “the memory,” “the transceiver,” “the antenna,” etc.), unless otherwise specifically stated, should be understood to refer to one or more elements (e.g., “one or more processors,” “one or more controllers,” “one or more memories,” “one or more transceivers,” etc.). The terms “set” and “group” are intended to include one or more elements, and may be used interchangeably with “one or more.” Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions. Unless specifically stated otherwise, the term “some” refers to one or more. All structural and functional equivalents to the elements of the various aspects described throughout this disclosure that are known or later come to be known to those of ordinary skill in the art are intended to be encompassed by the claims. Moreover, nothing disclosed herein is intended to be dedicated to the public regardless of whether such disclosure is explicitly recited in the claims.

1. A radio frequency (RF) circuit, comprising:
a transceiver package comprising:
a signal chain comprising one or more mixers coupled to one or more amplifiers; and
a noise source circuit coupled to the signal chain, the noise source circuit comprising:
a noise generator circuit comprising a first inverter topology, wherein the noise generator circuit is configured to output noise within a range of frequencies; and
an amplifier circuit comprising a second inverter topology, wherein the amplifier circuit is coupled to the noise generator circuit, wherein the amplifier circuit is configured to amplify the noise and feed the amplified noise to the signal chain.

2. The RF circuit of claim 1, wherein the first inverter topology comprises a complementary metal oxide semiconductor (CMOS) transistor topology.

3. The RF circuit of claim 1, wherein the first inverter topology comprises a diode-coupled inverter.

4. The RF circuit of claim 1, wherein the second inverter topology comprises a complementary metal oxide semiconductor (CMOS) transistor topology.

5. The RF circuit of claim 1, wherein:
the noise generator circuit comprises:
a first output node;
a first transistor including a drain coupled to the first output node; and
a second transistor including a drain coupled to the first output node; and
the amplifier circuit comprises:
a second output node;
a third transistor including a gate coupled to the first output node and a drain coupled to the second output node; and
a fourth transistor including a gate coupled to the first output node and a drain coupled to the second output node.

6. The RF circuit of claim 1, further comprising one or more memories; and one or more processors coupled to the one or more memories, wherein:
the one or more processors are configured to cause the noise source circuit to:
feed, to the signal chain at a first time occasion, first noise at a first power level associated with a first state; and
feed, to the signal chain at a second time occasion, second noise at a second power level associated with a second state.

7. The RF circuit of claim 6, wherein the one or more processors are configured to:
obtain a first characteristic associated with the signal chain based on the first noise fed at the first power level;
obtain a second characteristic associated with the signal chain based on the second noise fed at the second power level; and
determine a noise figure associated with the signal chain based at least in part on a comparison of the first characteristic and the second characteristic.

8. The RF circuit of claim 1, wherein:
the signal chain comprises a receive chain configured to receive an RF signal; and
the noise generator circuit is configured to feed the amplified noise to the one or more amplifiers.

9. The RF circuit of claim 1, wherein:
the signal chain comprises a transmit chain configured to transmit an RF signal; and
the noise generator circuit is configured to feed the amplified noise to the one or more mixers.

10. A radio frequency (RF) circuit, comprising:
a transceiver package comprising:
a signal chain comprising one or more mixers coupled to one or more amplifiers; and
a current-mode noise source circuit coupled to the signal chain, wherein the current-mode noise source circuit is configured to feed noise to the signal chain, the current-mode noise source circuit comprising:
an output node;
a current-mirror circuit;
an amplifier circuit coupled to the output node and the current-mirror circuit;
a current-sink circuit coupled to the output node and the current-mirror circuit; and
a variable resistive element coupled to the output node.

11. The RF circuit of claim 10, wherein the current-mode noise source circuit further comprises an inverter circuit configured to output balanced control signaling.

12. The RF circuit of claim 11, wherein the amplifier circuit comprises:
a cascode transistor topology; and
a switch circuit coupled to a gate of a transistor of the cascode transistor topology, wherein the inverter circuit is configured to feed the balanced control signaling to the switch circuit.

13. The RF circuit of claim 10, wherein the current-sink circuit comprises a cascode transistor topology.

14. The RF circuit of claim 10, wherein the variable resistive element comprises a digital potentiometer.

15. The RF circuit of claim 10, wherein an excess noise ratio associated with the current-mode noise source circuit depends at least in part on a first channel width of a first transistor of the current-mirror circuit and a second channel width of a second transistor of the amplifier circuit.

16. The RF circuit of claim 10, further comprising one or more memories; and one or more processors coupled to the one or more memories, wherein the one or more processors are configured to cause the current-mode noise source circuit to:
feed, to the signal chain at a first time occasion, first noise at a first power level associated with a first state; and
feed, to the signal chain at a second time occasion, second noise at a second power level associated with a second state.

17. The RF circuit of claim 16, wherein the one or more processors are configured to:
obtain a first characteristic associated with the signal chain based on the first noise fed at the first power level;
obtain a second characteristic associated with the signal chain based on the second noise fed at the second power level; and
determine a noise figure associated with the signal chain based at least in part on a comparison of the first characteristic and the second characteristic.

18. The RF circuit of claim 10, wherein:
the signal chain comprises a receive chain configured to receive an RF signal; and
the current-mode noise source circuit is configured to feed the noise to the one or more amplifiers.

19. The RF circuit of claim 10, wherein:
the signal chain comprises a transmit chain configured to transmit an RF signal; and
the current-mode noise source circuit is configured to feed the noise to the one or more mixers.

20. A method for noise figure characterization of a signal chain, comprising:
feeding, via a noise source circuit to a signal chain at a first time occasion, first noise at a first power level associated with a first state, wherein a transceiver package comprises the signal chain and the noise source circuit, wherein the signal chain comprises one or more mixers coupled to one or more amplifiers, wherein the noise source circuit comprises a noise generator circuit and an amplifier circuit;
feeding, via the noise source circuit to the signal chain at a second time occasion, second noise at a second power level associated with a second state;
obtaining a first characteristic associated with the signal chain based on the first noise fed at the first power level;
obtaining a second characteristic associated with the signal chain based on the second noise fed at the second power level; and
determining a noise figure associated with the signal chain based at least in part on a comparison of the first characteristic and the second characteristic.
